(19) United States
(12) Patent Application Publication
(10) Pub. No.: US 2006/0115922 A1
(43) Pub. Date: Jun. 1, 2006

(54) Photo movie creating method, apparatus, and program

(75) Inventors: Hajime Araya, Kanagawa (JP); Eiichi Kito, Kanagawa (JP); Takayuki Iida, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/231,757

(22) Filed: Sep. 22, 2005

(30) Foreign Application Priority Data
Sep. 22, 2004 (JP) 2004-276041

(51) Int. Cl. H01L 21/00

(52) U.S. Cl. 438/61

(57) ABSTRACT

A photo movie creating apparatus stores a photo movie creating program. When the photo movie creating program is started, a position detecting section and an image editing section are generated in the CPU. The position detecting section detects a distance L1 from the center to the edge of a cropping frame for cropping a target subject out of a still image, and a distance L2 from the center of the target subject to the edge of the still image on this cropping frame's edge side. The image editing section compares the distance L1 with the distance L2, then controls at least one of the size and the position of the cropping frame so as the cropping frame not to protrude outside the still image where no image data exists.

### BACKGROUND OF THE INVENTION

1. Field of the Invention

The present invention relates to a photo movie creating method and apparatus, and also relates to a photo movie creating program for operating computers to create the photo movies.

2. Background Arts

Various methods have been offered to create photo movies (that is, pseudo moving pictures) by editing still images captured with digital cameras or the like. (see, for example, the Japanese patent laid-open publications No. 6-14292 and No. 6-30380). In these photo movie creating methods, firstly created is a scenario, which reflects the user's idea of a photo movie. According to this scenario, the still images are selected, converted (e.g. enlargement, reduction, and rotation of the images), masked (cutting out or pasting portions of the images), moved, or synthesized to create the photo movie. The created photo movie is played back on the display monitor of a personal computer, and they can also be stored in a storage medium such as a DVD (Digital Versatile Disc) or be printed out thorough a printer.

At the same time, a picture image playback method is offered where the image data of a still image is stored in an image file together with scenario data representing a zoom value and a zoom position of the zoomed version of the same still image, so that the still image can be followed by the zoomed image at a playback according to the scenario data (see the Japanese patent laid-open publication No. 2001-94924).

The picture image playback method of this kind provides a cropping frame to crop a target subject (or a subject of interest) out of a still image. And in this operation, the center of the cropping frame will normally be placed onto the center of the target subject. Unfortunately, if the target subject lies near the edge of the still image, a region with no image data may sometime be cropped out from outside the still image. The region with no image data appears as a blacked out image at a playback, and the photo movie will thus look unattractive.

### SUMMARY OF THE INVENTION

In view of the foregoing, an object of the present invention is to provide a photo movie creating method, apparatus, and program to create attractive photo movies.

To achieve the above object and other objects, the photo movie creating method and program of the present invention include a step of detecting a positional relationship among an edge of the still image, a cropping frame, and a target subject before cropping a specific portion including the target subject out of the still image, and a step of controlling at least one of size and a position of the cropping frame based on the result of the detection so as cropping frame not to protrude outside the still image where no image data exists.

In the detecting step, a distance L1 from the center to the edge of the cropping frame and a distance L2 from the center of the target subject to the edge of the still image on this cropping frame's edge side are detected. In the controlling step, the distance L1 is compared with the distance L2 and the size or position of the cropping frame is changed if the distance L1 is larger than the distance L2.

The photo movie creating apparatus of the present invention includes a position detector for detecting a positional relationship among an edge of the still image, a cropping frame, and a target subject before cropping a specific portion including the target subject out of the still image, and an image editor for controlling at least one of size and a position of the cropping frame based on the result of the detection so as the cropping frame not to protrude outside the still image where no image data exists.

The position detector detects a distance L1 from the center to the edge of the cropping frame and a distance L2 from the center of said target subject to the edge of said still image on said cropping frame's edge side. And the image editor compares the distance L1 with the distance L2 and change the size or position of the cropping frame if the distance L1 is larger than the distance L2.

According to the photo movie creating method, apparatus, and program of the present invention, at least one of the size and position of the cropping frame will be controlled. As the result, the cropping frame does not protrude outside the still image where no image data exists, and attractive photo movies will be created.

### BRIEF DESCRIPTION OF THE DRAWINGS

For more complete understanding of the present invention, and the advantage thereof, reference is now made to the following descriptions taken in conjunction with the accompanying drawings, in which:

FIG. 1 is a block diagram of a photo movie creating apparatus in accordance with the present invention;

FIGS. 2A to 2C are explanatory views of scenes created by the photo movie creating apparatus, in which FIGS. 2A and 2B illustrate the scenes resulting from a zooming process, while FIG. 2C illustrates the scene resulting from a panning process;

FIG. 3 is a explanatory view illustrating a positional relationship among a still image, a cropping frame, and a target subject;

FIGS. 4A to 4C are explanatory views of position control to the cropping frame, in which FIG. 4A illustrates the positional relationships among the still image, cropping frame, and target subject with and without the control, while FIGS. 4B and 4C respectively illustrate the scenes with the control and the scenes without the control;

FIGS. 5A to 5C are explanatory views of size control to the cropping frame, in which FIG. 5A illustrates the positional relationships among the still image, cropping frame, and target subject with and without the control, while FIGS. 5B and 5C respectively illustrate the scenes with the control and the scenes without the control;

FIG. 6 is a flow chart of a creating process for the photo movie.

### DESCRIPTION OF THE PREFFERED EMBODIMENTS

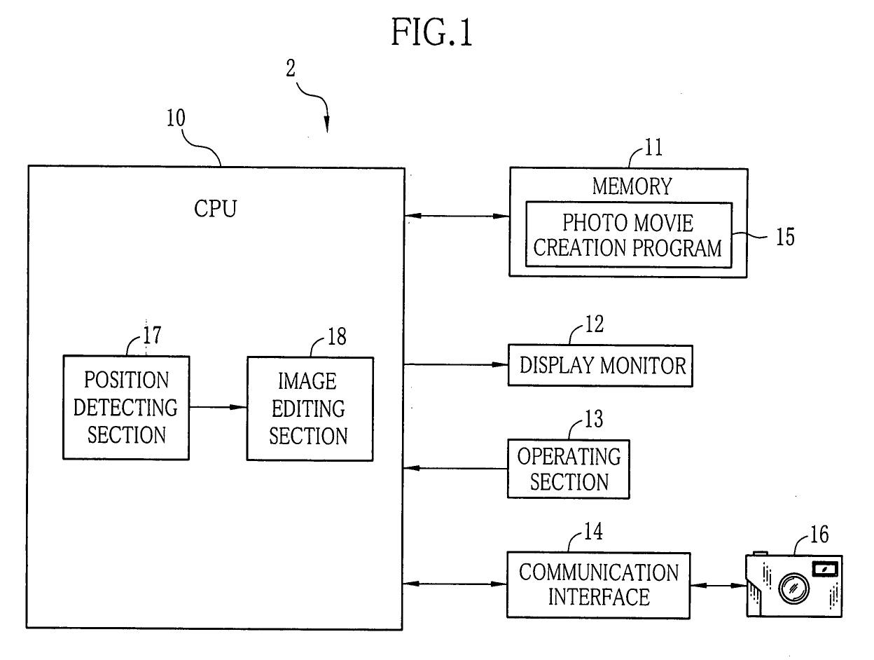

Referring to FIG. 1, a photo movie creating apparatus 2 is under the control of a CPU 10. The CPU 10 is connected with a memory 11, a display monitor 12, an operating section 13, and a communication interface 14.

The memory 11 stores a photo movie creating program 15 as well as various programs and data needed for starting the photo movie creating apparatus 2. The memory 11 also stores image data, which is sent from a digital camera 16 through the communication interface 14, and created photo movies.

The display monitor 12 displays the above described image data and photo movies. The operating section 13 includes a keyboard, a mouse and some such to set up various parameters for image editing. In response to the operating section 13, the CPU 10 controls each element in the photo movie creating apparatus 2. The communication interface 14 sends and receives data to and from an external device such as the digital camera 16.

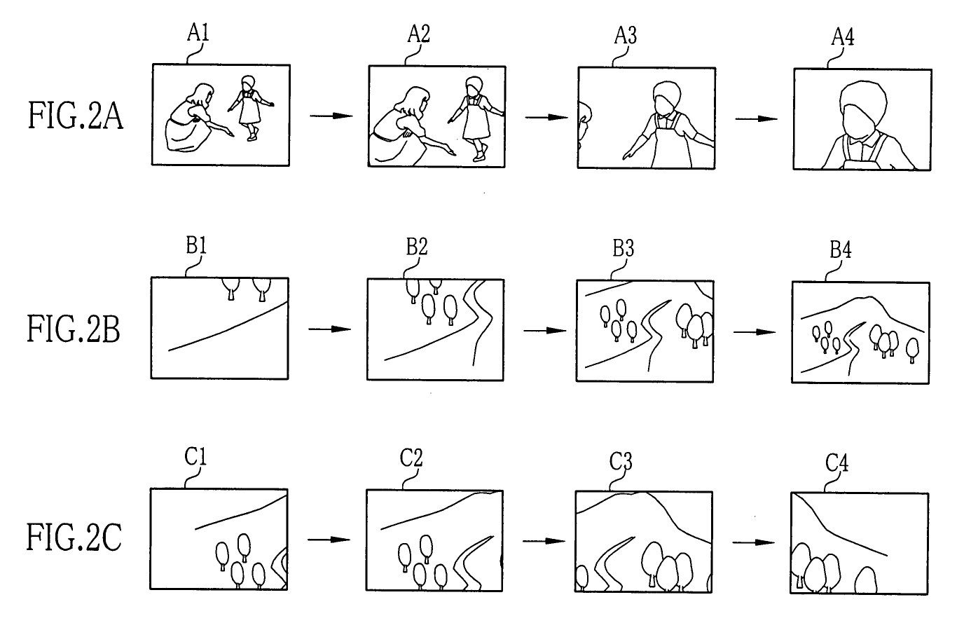

The photo movie creating apparatus 2 executes such image processes as an electronic zooming process and a panning process to still images to create, for example, scenes A to C shown in FIGS. 2A to 2C. The scene A in FIG. 2A begins with a frame A1 of a parent and a child, proceeds to frames A2 and A3 of the child's face zoomed up gradually, then reaches a frame A4 which is a close-up shot of the child's face. The frames A1 to A4 of the scene A are created through the electronic zooming process, where some partial images of different magnification are cropped out while a zoom point is fixed at a certain portion corresponding to the frame A1 in the still image.

The scene B in FIG. 2B begins with a frame B1 of a land surface and a road, then gradually zooms out to reach a frame B4 of a distant view of a mountain right down the road. The frames B1 to B4 of the scene B are created in the same way as the scene A, where some partial images of different magnification are cropped out while the zoom point is fixed at a certain portion corresponding to the frame B4 in the still image.

The scene C in FIG. 2C begins with a frame C1 showing the left foot of a mountain, proceeds to frames C2 and C3 showing the center portion of the mountain, then reaches a frame C4 showing the right foot of the mountain as if the camera is moving from left to right. The frame C1 to C4 of the scene C are created of partial images cropped out from the still image of the distant view. The photo movie creating apparatus 2 couples these scenes together to create a photo movie. In the above embodiments, every scene is explained with four frames for the sake of simplicity, but in reality each scene contains quite a lot of frames.

A main image to be featured in the zooming process or the panning process is determined by the user specifying a target subject (for example, a person's face or a landmark such as a building and a mountaintop) in a still image through the operating section 13 of the photo movie crating apparatus 2. Alternatively, a main image may automatically be extracted through the image recognition technique well known in the art. Taking the scene A in FIG. 2A as an example, the main image is the frame A4, and the target subject is the child's face. The cropping frames for the frames A1 to A3 are separately determined in size and position based on preset conditions contained in the photo movie creating program 15.

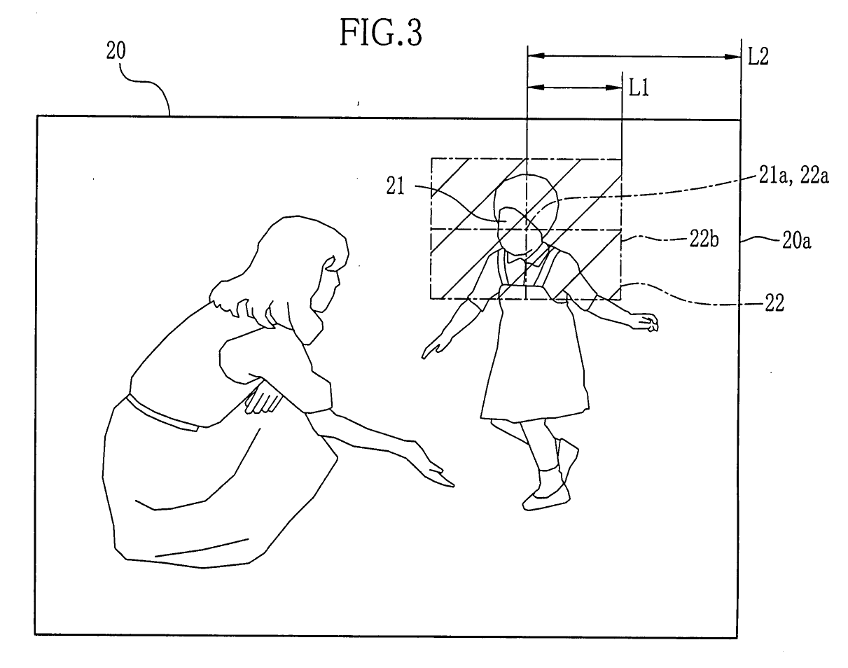

Referring back to FIG. 1, when the operating section 13 is operated to start the photo movie creating program 15, a position detecting section 17 and an image editing section 18 are generated in the CPU 10. As shown in FIG. 3, for the electronic zooming process or the panning process, a cropping frame 22 (shown by a chain line in the figure) is displayed for cropping out a specific portion (a shaded area in the figure) that includes a target subject 21 (the child's face in this case) in a still image 20. The position detecting section 17 detects two distances, a distance L1 from a center 22a to an edge 22b of the cropping frame 22 and a distance L2 from a center 21a of the target subject 21 (i.e. the center of the child's face in this case) to an edge 20a of the still image 20 on the edge 22b side. Then the position detecting section 17 sends the detected values of the distances L1 and L2 to the image editing section 18. For the sake of simplicity, FIG. 3 shows the distances L1 and L2 only on the right side of the still image 20. The position detecting section 17 rather detects, in reality, the distances L1 and L2 on all four sides of the left, right, top, and bottom.

Based on the detection results of the position detecting section 17, the image editing section 18 controls at least one of the size and position of the cropping frame 22 so as the cropping frame 22 not to protrude outside the still image 20, a region with no image.

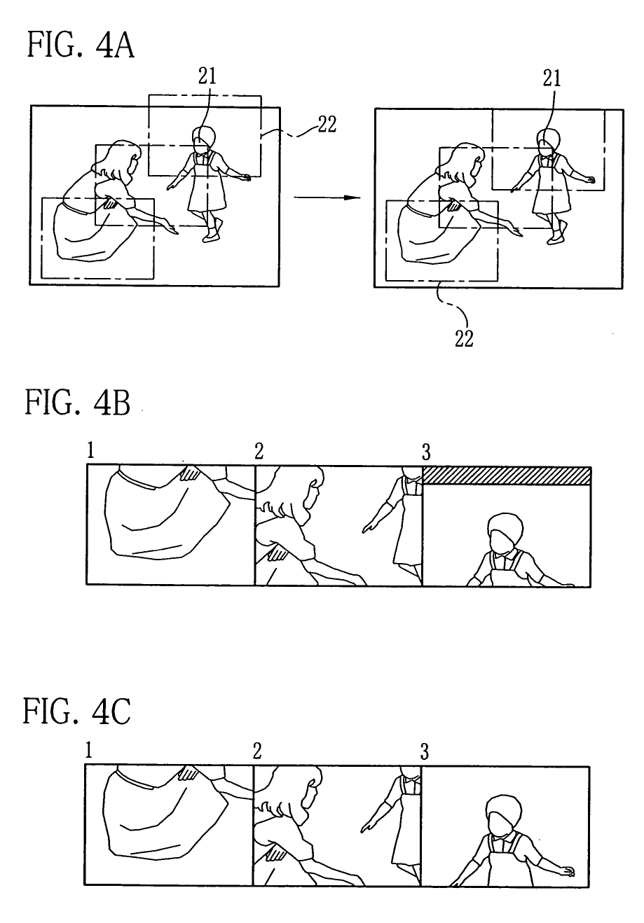

In particular, the image editing section 18 compares the distance L1 with the distance L2, and brings down the cropping frame 20, as shown in FIG. 4A, if the distance L1 is larger than the distance L2. In FIG. 4B, the scenes without this control comes to have a frame 3 whose upper side contains the no image region as a blacked out image (a hatched area in the figure). In FIG. 4C, on the other hand, the scenes with this control does not have any frames with blacked out images.

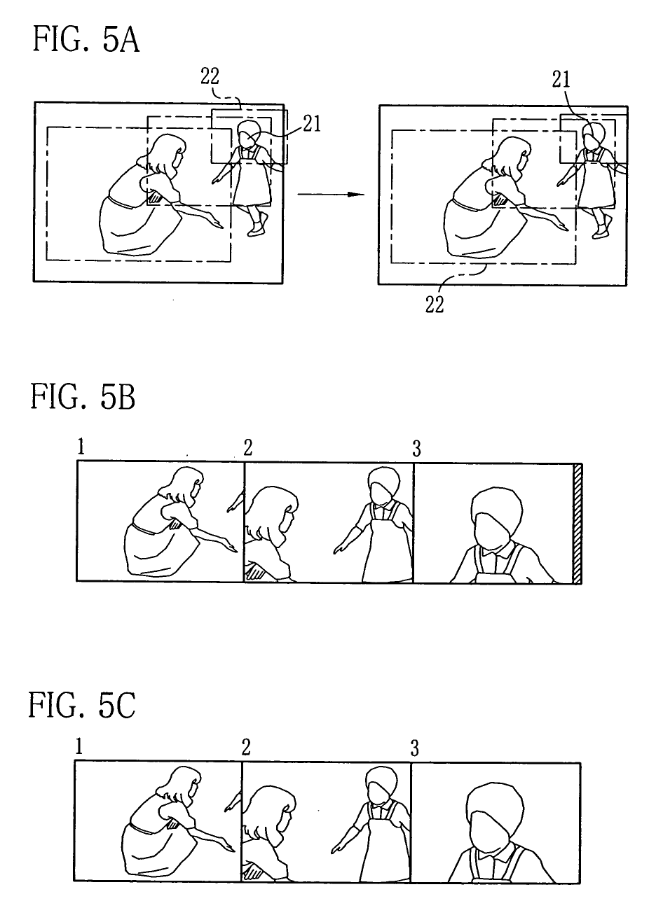

Alternatively, as shown in FIG. 5A, the image editing section 18 may reduce the size of the cropping frame 22 for the frame 3 while maintaining the center 22a of the cropping frame 22 on the center 21a of the target subject 21. In FIG. 5B, the scenes without this control comes to have a frame 3 whose upper side contains the no image region as a blacked out image (a hatched area in the figure) just like in FIG. 4B. In FIG. 5C, on the other hand, the scenes with this control does not have any frames with blacked out images.

If the distance L1 is smaller than the distance L2, the image editing section 18 places the cropping frame 22 so that the center 22a of the cropping frame 22 will match the center 21a of the target subject 21.

While controlling the size and position of the cropping frame 22, the image editing section 18 will select, convert (enlargement, reduction, rotation of the image), mask (cutting out or pasting portions of the images), move, or synthesize the still images to create a photo movie based on a scenario, which is entered from the operating section 13 according to the user's idea of the photo movie. In response to this entry, the CPU 10 displays the created photo movie on the display monitor 12 and stores the photo movie in the memory 11.

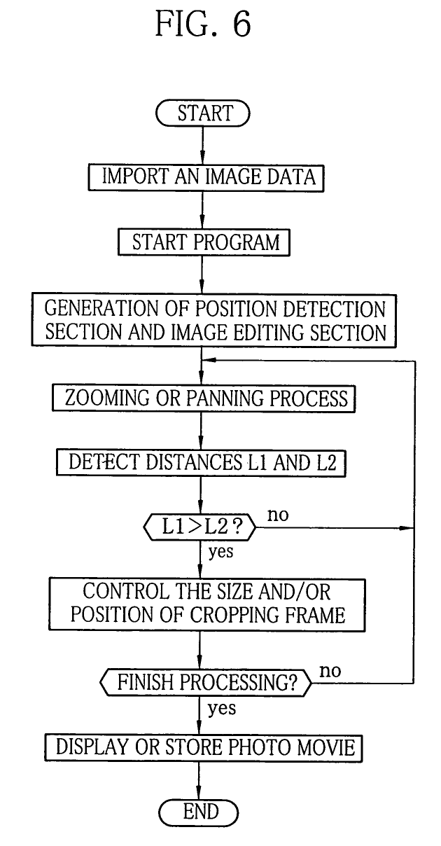

The operation of the above construction is now explained with reference to a flow chart in FIG. 6. When the photo movie creating apparatus 2 is turned on, and the digital camera 16 is connected with the communication interface 14, the image data is loaded from the digital camera 16 to the memory 11. Then, the photo movie creating program 15 is started upon operation of the operating section 13.

When the photo movie creating program 15 is started, the position detecting section 17 and the image editing section 18 are generated in the CPU 10. Once a main image for the zooming process or the panning process is determined, the position detecting section 17 detects the distance L1, from the center 22a of the cropping frame 22 to the edge 22b of the same cropping frame 22, and the distance L2, from the center 21a of the target subject to the edge 20a on the edge 22b side of the still image 20, with respect to all four sides of left, right, top, and bottom. The values of the distances L1 and L2 are transmitted from the position detecting section 17 to the image editing section 18.

The image editing section 18 compares these two distances, L1 and L2, about each side. If the distance L1 is larger than the distance L2, the image editing section 18 controls at least one of the size and position of the cropping frame 22 so as the cropping frame 22 not to protrude to no image containing regions outside the still image 20. If the distance L1 is smaller than the distance L2, to the contrary, the image editing section 18 places the cropping frame 22 so that the center 22a of the cropping frame 22 will match the center 21a of the target subject 21. While controlling the cropping frame 22, the image editing section 18 executes various processes to the image to create a photo movie based on a scenario, which is entered from the operating section 13 according to the user's idea of the photo movie. The created photo movie is displayed on the display monitor 12 and is also stored in the memory 11.

Since the cropping frame 22 is controlled not to protrude outside the still image 20, i.e. the no image containing region which appears as a blacked out image at a playback, the photo movie will look attractive.

The above embodiment uses the cropping frame 22 of rectangular shape, it is however possible to use the cropping frame of, for example, circular shape or star shape.

The special effects of the above embodiment are mere examples, and the present invention is not limited to these kinds of effect. In addition, the present invention can also be applicable to a photo movie created from a single piece of still image.

The photo movie creating apparatus 2 may optionally incorporate a DVD recorder to store the photo movies in DVDs, or it may be connected with a printer to print out any intended scenes in the photo movies.

As described so far, the present invention is not to be limited to the above embodiments, and all matter contained herein is illustrative and does not limit the scope of the present invention. Thus, obvious modifications may be made within the spirit and scope of the appended claims.

What is claimed is:

1. A photo movie creating method for creating a photo movie by editing still images, comprising the steps of:
detecting a positional relationship among an edge of said still image, a cropping frame, and a target subject before cropping a specific portion including said target subject out of said still image; and
controlling at least one of size and a position of said cropping frame based on the result of said detection so as said cropping frame not to protrude outside said still image where no image data exists.

2. A photo movie creating method as claimed in claim 1, wherein said detecting step detects a distance L1 from the center to the edge of said cropping frame and a distance L2 from the center of said target subject to the edge of said still image on said cropping frame's edge side.

3. A photo movie creating method as claimed in claim 2, wherein said controlling step matches the center of said cropping frame to the center of said target subject.

4. A photo movie creating method as claimed in claim 3, wherein said controlling step compares said distance L1 with said distance L2 and changes the position of said cropping frame if said distance L1 is larger than said distance L2.

5. A photo movie creating method as claimed in claim 3, wherein said controlling step compares said distance L1 with said distance L2 and changes the size of said cropping frame if said distance L1 is larger than said distance L2.

6. A photo movie creating apparatus for creating a photo movie by editing still images, comprising:
a position detector for detecting a positional relationship among an edge of said still image, a cropping frame, and a target subject before cropping a specific portion including said target subject out of said still image; and
an image editor for controlling at least one of size and a position of said cropping frame based on the result of said detection so as said cropping frame not to protrude outside said still image where no image data exists.

7. A photo movie creating apparatus as claimed in claim 6, wherein said position detector detects a distance L1 from the center to the edge of said cropping frame and a distance L2 from the center of said target subject to the edge of said still image on said cropping frame's edge side.

8. A photo movie creating apparatus as claimed in claim 7, wherein said image editor matches the center of said cropping frame to the center of said target subject.

9. A photo movie creating apparatus as claimed in claim 8, wherein said image editor compares said distance L1 with said distance L2 and changes the position of said cropping frame if said distance L1 is larger than said distance L2.

10. A photo movie creating apparatus as claimed in claim 8, wherein said image editor compares said distance L1 with said distance L2 and changes the size of said cropping frame if said distance L1 is larger than said distance L2.

11. A photo movie creating program to operate a computer to create a photo movie by editing still images, comprising the steps of:
detecting a positional relationship among an edge of said still image, a cropping frame, and a target subject before cropping a specific portion including said target subject out of said still image; and
controlling at least one of size and a position of said cropping frame based on the result of said detection so as said cropping frame not to protrude outside said still image where no image data exists.

12. A photo movie creating program as claimed in claim 11, wherein said detecting step detects a distance L1 from the center to the edge of said cropping frame and a distance L2 from the center of said target subject to the edge of said still image on said cropping frame's edge side.

13. A photo movie creating program as claimed in claim 12, wherein said controlling step matches the center of said cropping frame to the center of said target subject.

14. A photo movie creating program as claimed in claim 13, wherein said controlling step compares said distance L1 with said distance L2 and moves said cropping frame if said distance L1 is larger than said distance L2.

15. A photo movie creating program as claimed in claim 13, wherein said controlling step compares said distance L1 with said distance L2 and changes the size of said cropping frame if said distance L1 is larger than said distance L2.
